(19) United States
(12) Patent Application Publication
(10) Pub. No.: US 2026/0253548 A1
(43) Pub. Date: Aug. 27, 2026

(54) PIXEL CIRCUIT AND DISPLAY DEVICE COMPRISING THE SAME

(71) Applicant: ADRC. CO. KR, Seoul (KR)

(72) Inventors: Jin JANG, Seoul (KR); Jaein Noh, Seoul (KR)

(21) Appl. No.: 19/182,920

(22) Filed: Apr. 18, 2025

(30) Foreign Application Priority Data
Feb. 25, 2025 (KR) 10-2025-0024645

(51) Int. Cl. G09G 3/3233

(52) U.S. Cl. CPC G09G 3/3241; G09G 3/3233; G09G 3/3258; G09G 2300/043; G09G 2300/0819; G09G 2320/0233

(57) ABSTRACT

A pixel circuit includes a light emitting diode, a first transistor including one end connected to the light emitting diode, a first capacitor including one end connected to a gate of the first transistor, a second capacitor including one end connected to the other end of the first transistor, a second transistor including one terminal connected to the other end of the second capacitor and the other end supplied with a reference voltage, a third transistor including one end connected to the other end of the first transistor and the other end supplied with a power voltage, and a fourth transistor including one end connected to the other end of the second capacitor and the other end connected to the gate of the first transistor. A first voltage, which is a data signal supplied to one end of the first transistor plus a threshold voltage of the first transistor, is provided to the gate of the first transistor during the on period of the fourth transistor.

### CROSS-REFERENCE TO RELATED APPLICATION

This application claims priority to and the benefit of Korean Patent Application No. 10-2025-0024645 filed at the Korean Intellectual Property Office on Feb. 25, 2025, the entire contents of which are incorporated herein by reference.

### BACKGROUND

### (a) Technical Field

The present disclosure relates to a pixel circuit and a display device including the same.

### (b) Description of the Related Art

In driving active matrix displays containing a plurality of light emitting diodes, low-temperature polysilicon (LTPS) thin-film transistors (TFT) are generally used to control precise current flow. However, an excimer laser annealing (ELA) process used to manufacture LTPS TFTs is a high-cost process, which has the disadvantage of increasing the manufacturing cost of the LTPS TFTs. On the other hand, oxide TFTs may be manufactured at lower cost than LTPS TFTs. However, oxide TFTs easily operate in depletion mode and have the problem of unstable bias.

### SUMMARY

The present disclosure attempts to provide a pixel circuit including an oxide TFT and a display device including the same.

A pixel circuit according to a feature of the present disclosure includes a light emitting diode, a first transistor including one end connected to the light emitting diode, a first capacitor including one end connected to a gate of the first transistor, a second capacitor including one end connected to the other end of the first transistor, a second transistor including one terminal connected to the other end of the second capacitor and the other end supplied with a reference voltage, a third transistor including one end connected to the other end of the first transistor and the other end supplied with a power voltage, and a fourth transistor including one end connected to the other end of the second capacitor and the other end connected to the gate of the first transistor. A first voltage, which is a data signal supplied to one end of the first transistor plus a threshold voltage of the first transistor, is provided to the gate of the first transistor during the on period of the fourth transistor.

The first voltage may decrease by the gate voltage change by a subthreshold swing (SS) of the first transistor during the on period of the fourth transistor.

The pixel circuit may include a fifth transistor including one end connected to one end of the first transistor and the other end supplied with the data signal, and a sixth transistor including one end connected to the other end of the first capacitor and the other end supplied with an initialization voltage. A first scan signal may be supplied to the gate of the fifth transistor, a second scan signal may be supplied to the gate of the fourth transistor and the gate of the sixth transistor, and a first light emitting signal may be supplied to the gate of the second transistor and the gate of the third transistor. In driving the pixel circuit, a first period in which the second scan signal and the first light emitting signal are at on level, a second period in which the first scan signal and the second scan signal are at on level, a third period in which the second scan signal is at the on level, and a fourth period in which the first light emitting signal is at the on level may be divided. In the second period, the data signal may be provided to one end of the first transistor, and the first voltage may be provided to the gate of the first transistor, and in the third period, the first voltage may decrease by the amount of gate voltage change by the SS of the first transistor.

The pixel circuit may include a seventh transistor connected between one end of the first transistor and the light emitting diode and including a gate to which a second light emitting signal at the on level is supplied a predetermined period earlier than the first light emitting signal. In driving the pixel circuit, a first period in which the second scan signal and the first light emitting signal are at the on level, a second period in which the first scan signal and the second scan signal are at the on level, a third period in which the second scan signal is at the on level, and a fourth period in which the first light emitting signal and the second light emitting signal are at the on level may be divided. In the second period, the data signal may be provided to one end of the first transistor, and the first voltage may be provided to the gate of the first transistor; in the third period, the first voltage may decrease by the amount of gate voltage change by the SS of the first transistor so that the gate of the first transistor becomes the second voltage; and in the fourth period, a driving current generated by the first transistor according to the second voltage may flow to the light emitting diode. The first to seventh transistors may be implemented as oxide transistors.

A display device according to another feature of the present disclosure may include a plurality of first scan lines, a plurality of second scan lines, a plurality of data lines, a plurality of light emitting control lines, and a plurality of pixels. Each of the plurality of pixels includes a light emitting diode, a first transistor including one end connected to the light emitting diode, a first capacitor including one end connected to a gate of the first transistor, a second capacitor including one end connected to the other end of the first transistor, a second transistor including one end connected to the other end of the second capacitor, the other end supplied with a reference voltage, and a gate connected to a corresponding first light emitting control line among the plurality of light emitting control lines, a third transistor including one end connected to the other end of the first transistor, the other end supplied with a power voltage, and a gate connected to the first light emitting control line, a fourth transistor including one end connected to the other end of the second capacitor, the other end connected to the gate of the first transistor, and a gate connected to a corresponding second scan line among the plurality of second scan lines, and a fifth transistor including one end connected to one end of the first transistor, the other end connected to a corresponding first data line among the plurality of data lines, and a gate connected to a corresponding first scan line among the plurality of first scan lines.

While a first scan signal of the on level is supplied through the corresponding first scan line and a second scan signal of the on level is supplied through the corresponding second scan line, a first voltage obtained by adding a threshold voltage of the first transistor to the data signal supplied to one end of the first transistor may be provided to the gate of the first transistor. While the first scan signal is at an off level and the second scan signal of the on level is supplied through the corresponding second scan line, the first voltage may decrease by the gate voltage change by a subthreshold swing (SS) of the first transistor during an on period of the fourth transistor.

Each of the plurality of pixels may further include a sixth transistor including one end connected to one end of the first capacitor, the other end supplied with an initialization voltage, and a gate connected to the corresponding second scan line, and a seventh transistor connected between one end of the first transistor and the light emitting diode, and including a gate connected to a second light emitting control line adjacent to the first light emitting control line among the plurality of light emitting control lines. While the first scan signal of the on level is supplied through the corresponding first scan line and the second scan signal of the on level is supplied through the corresponding second scan line, the first voltage obtained by adding the threshold voltage of the first transistor to the data signal supplied to one end of the first transistor may be provided to the gate of the first transistor, while the first scan signal is at an off level and the second scan signal of the on level is supplied through the corresponding second scan line, the first voltage may decrease by the gate voltage change by the subthreshold swing (SS) of the first transistor to become a second voltage during the on period of the fourth transistor, and while a light emitting signal of the on level is supplied to each of the first light emitting control line and the second light emitting control line, the first transistor may provide a driving current according to the second voltage to the light emitting diode. While the first scan signal is at an off level, the second scan signal of the on level is supplied through the corresponding second scan line, and the light emitting signal of the on level is supplied to the first light emitting control line, when the power voltage is applied to the other terminal of the first transistor and the initialization voltage is applied to an anode of the light emitting diode, the reference voltage may be applied to the other terminal of the second capacitor.

The first to seventh transistors may be implemented as oxide transistors.

The pixel circuit implemented with the oxide TFT may compensate for gate voltage change caused by threshold voltage and subthreshold swing of the driving transistor.

### BRIEF DESCRIPTION OF THE DRAWINGS

FIG. 1 is a cross-sectional view illustrating a cross-section of an oxide transistor according to an embodiment.

FIG. 2 is a graph showing the transfer characteristics of a switching TFT.

FIG. 3 is a graph showing the transfer characteristics of a driving TFT.

FIG. 4 is a graph showing the output characteristics of the driving TFT.

FIG. 5 is a circuit diagram illustrating a pixel circuit according to some embodiments.

FIG. 6 is a waveform diagram illustrating control signals supplied to the pixel circuit for an arbitrary period.

FIG. 7 is a schematic diagram conceptually illustrating voltage changes at each of a gate and a drain of a driving transistor by a charge-coupled diode connection of the driving transistor according to some embodiments.

FIG. 8 shows changes in a drain voltage and a gate voltage when a driving transistor T1 operates in the enhancement mode.

FIG. 9 is a waveform diagram showing changes in the drain voltage and the gate voltage of the driving transistor during a data input and VTH compensation period according to some embodiments.

FIG. 10A is a waveform of the drain voltage and FIG. 10B is a waveform of the gate voltage according to the threshold voltage range of the driving transistor of the pixel circuit according to some embodiments.

FIG. 11 is a graph showing the driving current error rate of the driving transistor operated according to FIG. 10.

FIG. 12A and FIG. 12B are waveform diagrams showing the gate voltage transient by SS when the SS compensation period is varied.

FIG. 13 is a graph showing the current error rate when the SS compensation period is varied.

FIG. 14 illustrates a display device including the pixel circuit according to some embodiments.

### DETAILED DESCRIPTION OF THE EMBODIMENTS

Hereinafter, embodiments of the present disclosure will be described in detail with reference to the accompanying drawings. In the present specification, the same or similar components will be denoted by the same or similar reference numerals, and duplicate descriptions thereof will be omitted.

In addition, when describing the embodiments disclosed in the present disclosure, if it is determined that a detailed description of a related known technology may obscure the gist of the embodiments disclosed herein, such a detailed description is omitted. The accompanying drawings are intended only to facilitate understanding of the exemplary embodiments disclosed in this specification, and it is to be understood that the technical ideas disclosed herein are not limited by the accompanying drawings and include all modifications, equivalents, or substitutions that are within the range of the ideas and technology of the present disclosure.

Although terms “first,” “second,” and the like are used to explain various components, the components are not limited to such terms. These terms are only used to distinguish one component from another component.

It is to be understood that when one component is referred to as being “connected” or “coupled” to another component, it may be connected or coupled directly to another component or there may be other intervening components. On the other hand, it is to be understood that when one component is referred to as being “connected” or “coupled directly” to another component, there are no other intervening components.

Throughout the specification, the terms “comprise” and “have” are intended to specify the presence of stated features, integers, steps, operations, components, parts, or a combination thereof, but do not preclude the presence or addition of one or more other features, integers, steps, operations, components, parts, and/or groups thereof.

FIG. 1 is a cross-sectional view illustrating a cross-section of an oxide transistor according to an embodiment.

FIG. 1 shows a cross-section of a coplanar polycrystalline indium-gallium-oxide (poly-IGO) TFT.

A buffer layer 102 of 100 nm SiO₂ may first be deposited on a glass substrate 101 at 420° C. using plasma-enhanced chemical vapor deposition (PECVD). An active layer 103 may be deposited using spray pyrolysis at 390° C., and may include 2 nm IGO (In:Ga=7:3) and 4 nm IGO (In:Ga=4:6) to control the resistance of the active layer 103. After patterning the active layer 103, a gate insulator (GI) 104 of 100 nm SiO₂ may be deposited by PECVD at 300° C., and a gate electrode 105 of 150 nm Mo may be deposited by sputtering at 150° C. A self-alignment process may be used to simultaneously pattern a gate metal and the GI. The gate electrode 105 may be implemented through a wet etching process, and N+ regions 106 and 107 may be formed for offset and source/drain contact through NF₃ plasma treatment. An interlayer 108 of 300 nm SiO₂ may be formed by deposition by PECVD at 300° C. To form source/drain electrodes 109 and 110, via holes 111 and 112 may be formed in the interlayer 108 by dry etching. The source/drain electrodes 109 and 110 may be formed by sputtering and patterning a 200 nm thick Mo layer. The formation process of the source/drain electrodes 109 and 110 may be completed by final vacuum annealing at 250° C. for 2 hours.

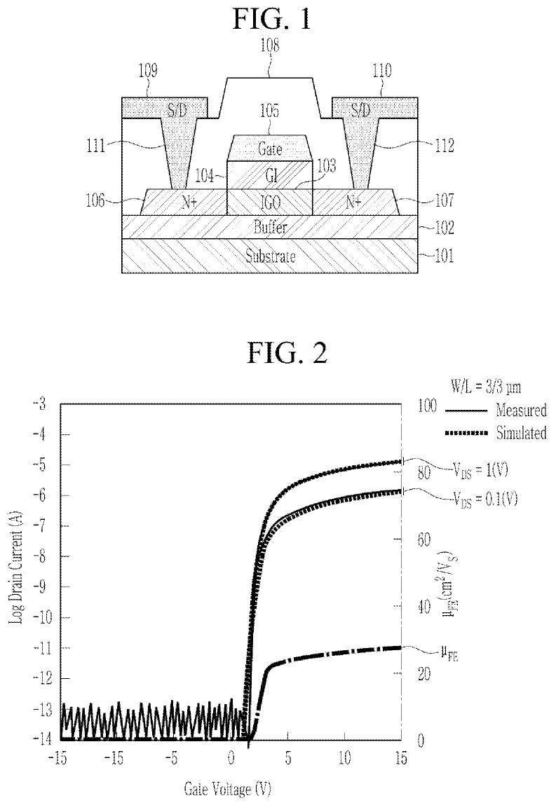

FIG. 2 is a graph showing the transfer characteristics of a switching TFT.

Field effect mobility μFE, threshold voltage VTH, and subthreshold swing (SS) values of the switching TFT may be 28 cm²/Vs, 1.0 V, and 0.24 V/dec, respectively. The SS value is the amount of gate voltage increase V required to increase the current by 10 times (decade) in a subthreshold region and may be represented in units of [V/dec]. In the present disclosure, the threshold voltage is defined as the gate voltage when the drain current reaches a predetermined threshold (e.g., W/L*10 Pa of the TFT), and the subthreshold region may include a region below the threshold voltage.

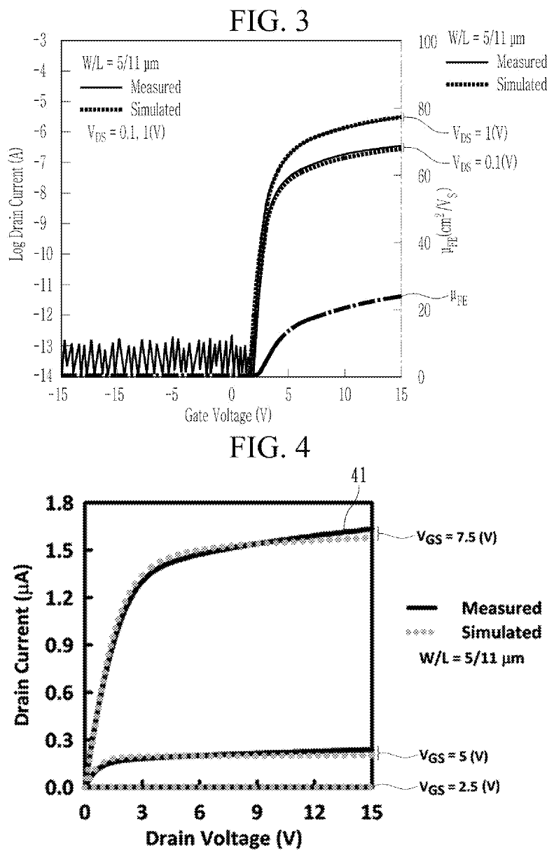

FIG. 3 is a graph showing the transfer characteristics of a driving TFT.

The field effect mobility μFE, the threshold voltage VTH, and the subthreshold swing SS of the driving TFT may each be 24 cm²/Vs, 1.0 V, and 0.32 V/dec, respectively. When the driving TFT having the characteristics of FIG. 3 is applied to the pixel circuit, the driving TFT may operate in the subthreshold region to represent a predetermined grayscale range. In the present disclosure, the width/length ratio of a channel between the switching TFT and the driving TFT may be different, but the threshold voltage may be the same.

FIG. 4 is a graph showing the output characteristics of the driving TFT.

A curve 41 in FIG. 4 shows the saturation characteristics of the driving TFT.

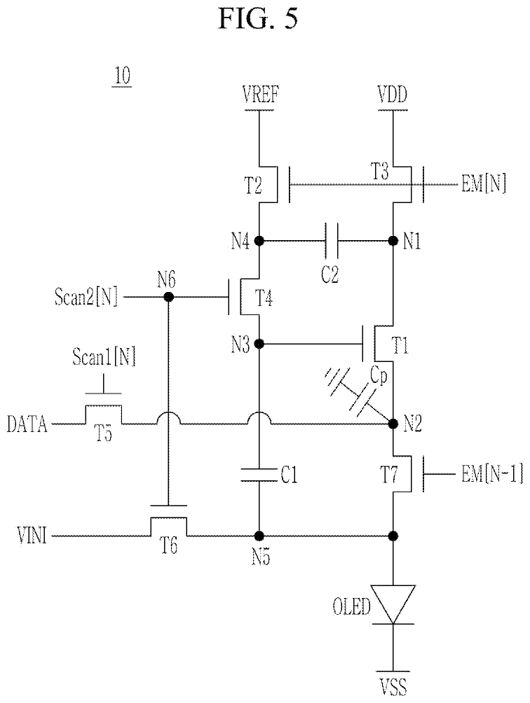

FIG. 5 is a circuit diagram illustrating a pixel circuit according to some embodiments.

A pixel circuit 50 illustrated in FIG. 5 may include seven oxide transistors T1-T7 and two capacitors C1 and C2. Each of the seven oxide transistors T1-T7 may have the TFT structure of FIG. 1 described above. Among the seven oxide transistors T1-T7, the driving transistor “T1” may operate according to the characteristic graphs of FIGS. 3 and 4. Among the seven oxide transistors T1-T7, the rest of switching transistors “T2-T7” may operate according to the characteristic graph of FIG. 2. A capacitor C1 may be a storage capacitor that stores a voltage according to a data signal, and a capacitor C2 may be a capacitor that compensates for the threshold voltage of the driving transistor T1.

The drain and source of the transistor T1 are each connected to a node N1 and a node N2, and the gate of the transistor T1 may be connected to a node N3. A reference voltage REF is supplied to the drain of a transistor T2, the source of the transistor T2 is connected to a node N4, and a light emitting signal EM[N] may be supplied to the gate of the transistor T2. A power voltage VDD is supplied to the drain of a transistor T3, the source of the transistor T3 is connected to the node N1, and the light emitting signal EM[N] may be supplied to the gate of the transistor T3. The drain and source of a transistor T7 are each connected to the node N2 and a node N5, and a light emitting signal EM[N−1] may be supplied to the gate of the transistor T7. The phase difference between the light emitting signal EM[N−1] and the light emitting signal (EM[N]) may be one horizontal period or a multiple of one horizontal period. In a display device including a plurality of pixel circuits, “one horizontal period” may refer to a period for programming a plurality of data signals to a plurality of pixels corresponding to each pixel row in order to drive a plurality of pixel rows within one vertical period corresponding to a unit frame.

A data signal DATA is supplied to the drain of a transistor T5, the source of the transistor T5 is connected to the node N2, and a first scan signal Scan1[N] may be supplied to the gate of the transistor T1. The drain and source of a transistor T4 are each connected to the node N4 and the node N3, and a second scan signal Scan2[N] may be supplied to the gate of the transistor T4. An initialization voltage INI is supplied to the drain of a transistor T6, the source of the transistor T6 is connected to the node N5, and the second scan signal Scan2[N] may be supplied to the gate of the transistor T6. The anode of a light emitting diode (LED) is connected to the node N5, and a power voltage VSS may be supplied to the cathode of the LED. The LED may be implemented as an organic light emitting diode or an inorganic light emitting diode. The power voltage VDD may be set to a voltage sufficiently high to enable the driving transistor T1 to supply a driving current ID to the LED according to a data signal VDATA. The power voltage VSS may be a low voltage, ground level or negative voltage. One end of the capacitor C1 is connected to the node N3, and the other end of the capacitor C1 may be connected to the node N5. One end of the capacitor C2 is connected to the node N1, and the other end of the capacitor C2 may be connected to the node N4.

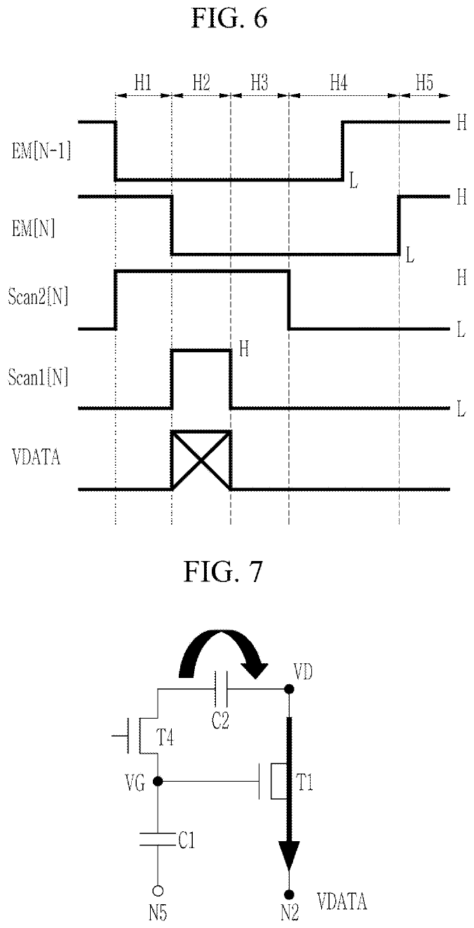

FIG. 6 is a waveform diagram illustrating control signals supplied to the pixel circuit for an arbitrary period.

In FIG. 6, the arbitrary period may be a period corresponding to a plurality of horizontal periods.

In the description below, the “on level” of a signal may refer to a level at which the corresponding signal may turn on a transistor among the switching transistors T2-T7 whose gates are supplied with the corresponding signal, and the “off level” of a signal may refer to a level at which the corresponding signal may turn off a transistor among the switching transistors T2-T7 whose gates are supplied with the corresponding signal. In the present disclosure, the on level may be a relatively higher level than the off level. In FIG. 6, the on level and the off level are represented by “H” and “L” respectively.

During a reset period H1, the light emitting signal EM[N] and the second scan signal Scan2[N] may be set to an on level H so that the transistors T2, T3, T4, and T6 may be turned on. At the same time, the light emitting signal EM[N−1] and the first scan signal Scan1[N] may be set to an off level L so that the transistors T5 and T7 may be turned off. During the reset period H1, the node N1 may be reset to the power voltage VDD, the node N3 and the node N4 may be reset to a reference voltage VREF, and the node N5 may be reset to an initialization voltage VINI.

A period “H2” is the data input and VTH compensation period. During the period H2, the light emitting signal EM[N] may be at the off level and the first scan signal Scan1[N] may be at the on level. Other signals may be maintained at the same level as in the period H1. During the period H2, when the transistors T2 and T3 are turned off and the transistor T5 is turned on, the data signal VDATA is supplied to the drain of the driving transistor T1. The drain voltage of the driving transistor T1 decreases due to the data signal VDATA, and the gate voltage of the driving transistor T1 also decreases. This is due to a “charge-coupled diode connection” through the capacitor C2 connected between the gate and drain of the driving transistor T1. In the present disclosure, the electrical state in which the transistor T4 is turned on and the gate and drain of the driving transistor T1 are connected through the capacitor C2 is referred to as the charge-coupled diode connection.

FIG. 7 is a schematic diagram conceptually illustrating voltage changes at each of the gate and the drain of a driving transistor by the charge-coupled diode connection of the driving transistor according to some embodiments.

As shown in FIG. 7, a drain voltage VD decreases along with the data voltage VDATA, and a gate voltage VG decreases by being coupled to the drain voltage VD by the capacitor C2.

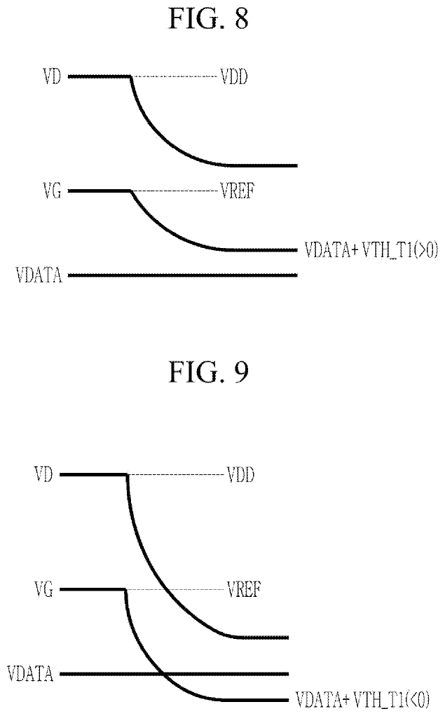

FIG. 8 is a waveform diagram showing changes in the drain voltage and the gate voltage of the driving transistor during a data input and VTH compensation period according to some embodiments.

FIG. 8 shows changes in the drain voltage and the gate voltage when a driving transistor T1 operates in the enhancement mode.

FIG. 9 is a waveform diagram showing changes in the drain voltage and the gate voltage of the driving transistor during the data input and VTH compensation period according to some embodiments.

FIG. 9 shows changes in the drain voltage and the gate voltage when the driving transistor T1 operates in depletion mode.

In the period H1, the gate and the drain of the driving transistor T1 are reset to the reference voltage VREF and the power voltage VDD, respectively. During the periods H1 and H2, the drain voltage of the driving transistor T1 is maintained at a voltage higher than the data signal VDATA. When the transistor T5 is turned on and the data signal VDATA is applied to the source of the driving transistor T1, the drain voltage of the driving transistor T1 decreases as shown in FIGS. 8 and 9. The drain and the gate of the driving transistor T1 are in the charge-coupled diode connection, so the gate voltage decreases as the drain voltage decreases. The gate voltage of the driving transistor T1 may be stabilized while reaching “VDATA+VTH_T1.”

Since the threshold voltage is a positive value in the enhancement mode, the gate voltage VDATA+VTH_T1 in FIG. 8 may be a higher voltage than the data signal VDATA. Since the threshold voltage is a negative voltage in the depletion mode, the gate voltage VDATA+VTH_1 in FIG. 9 may be a lower voltage than the data signal VDATA. That is, the gate voltage of the driving transistor T1 operating in the enhancement mode during the period H2 may be stabilized to a higher voltage than the source voltage, which is the data signal VDATA, by a threshold voltage VTH_T1. The gate voltage of the driving transistor T1 operating in the depletion mode during the period H2 may be stabilized to a lower voltage than the source voltage, which is the data signal VDATA, by the threshold voltage VTH_T1.

As such, each of the gate and the drain of the driving transistor T1 are reset to each of the reference voltage VREF and the power voltage VDD in the period H1, and the threshold voltage VTH_T1 of the driving transistor T1 may be extracted to the capacitor C2 through the charge coupling effect of the capacitor C2 in the period H2. In conventional pixel circuits, the drain voltage of the driving transistor becomes equal to the data signal before the threshold voltage of the driving transistor is stored in the capacitor. Then, since the capacitor could not store the threshold voltage of the driving transistor, it is difficult to compensate for the threshold voltage of the driving transistor.

On the contrary, in the present disclosure, the threshold voltage VTH_T1 may be extracted by the capacitor C2 as the gate voltage of the driving transistor T1 changes from the reference voltage VREF to “VDATA+VTH_T1” before the drain voltage of the driving transistor T1 reaches the data signal VDATA. The reference voltage VREF may be set to an appropriate level for such threshold voltage extraction. For example, the reference voltage VREF may be a voltage sufficiently lower than the power voltage VDD. As such, the pixel circuit 50 may stably store the negative threshold voltage VTH_T1 of the oxide TFT in the capacitor C2 by adding charge-coupling through the capacitor C2 to the diode connection.

A period “H3” is an SS compensation period to compensate for the subthreshold swing (SS) characteristics of the driving transistor T1. During the period H3, the first scan signal Scan1[N] is at the off level and the transistor T5 is turned off. Other signals, including the second scan signal Scan2[N], may be maintained at the same level as in the period H2. During the period H3, only the second scan signal Scan2[N] may be at the on level. When a gate-source voltage of the driving transistor T1 is below the threshold voltage, the swing of the gate voltage according to the current flowing in the driving transistor T1 is referred to as the subthreshold swing (SS). Generally, the SS characteristics differ for each of the plurality of driving transistors included in the display device due to process deviation. When the display device displays low grayscale, the uniformity of the low grayscale display may deteriorate due to SS deviation between driving transistors. If the SS deviation occurs between the plurality of driving transistors, the uniformity of low grayscale display may deteriorate. In order to prevent deterioration of the uniformity of the low grayscale display, the embodiment of the present disclosure may reflect a variation (ΔVss) of the gate voltage of the driving transistor T1 by the SS during the period H3. Then, the SS deviation between the plurality of driving transistors may be compensated during the actual light emitting period.

The data signal VDATA supplied to the node N2 during the period H2 may be maintained for the period H3 by a parasitic capacitor Cp connected to the source of the driving transistor T1. The parasitic capacitor Cp illustrated in FIG. 5 is only an example meant to facilitate understanding, and the present disclosure is not limited thereto. In the period H2, the gate voltage of the driving transistor becomes “VDATA+VTH_T1” by the data signal and the threshold voltage, and in the period H3, the transistor T4 is in on-state, so a change in the gate voltage of the driving transistor T1 may occur by the SS. As a result, the data signal input, the threshold voltage of the driving transistor T1, and the SS change are reflected, and the gate voltage of the driving transistor T1 may be represented by in the following Equation 1. In Equation 1, the change in the gate voltage by the SS is represented by “ΔVss,” and the gate voltage may be reduced by “ΔVss” due to the SS.

$$VG\_T1 = VDATA + VTH\_ 1 - T 1 - ΔV ss \qquad [ Equation 1 ]$$

A period “H4” is a period during which the SS compensation ends and the state of a pixel circuit 10 is maintained. During the period H4, the second scan signal Scan2[N] becomes off level and the transistors T4 and T6 turn off so that the compensation operation may be stopped. When the transistor T4 is turned off, the gate and the drain of the driving transistor T1 are electrically separated. During the period H4, the light emitting signal EM[N−1] is at the on level so that the transistor T7 may be turned on. However, since the transistor T3 is off and no voltage higher than the threshold voltage of the LED is supplied to the LED, no current flows.

A period “H5” is a period during which the pixel circuit 10 emits light according to the data signal written as the light emitting period. During the period H5, the light emitting signal EM[N] is at the on level, and the transistors T2 and T3 are turned on. During the period H5, the gate-source voltage of the driving transistor T1 may be maintained by the capacitor C1 connected to the gate of the driving transistor T1.

When the operating region of the driving transistor T1 according to the present disclosure is a subthreshold region, the driving current ID flowing through the driving transistor T1 is as shown in the following Equation 2.

$${I}_{OLED} = k \cdot exp ( \frac{( {V}_{DATA} - {ΔV}_{SS} - {V}_{INI} )}{SS / ln 10} ) \qquad [ Equation 2 ]$$

In Equation 2, k is the transconductance parameter of the driving transistor T1, ΔVss is the gate voltage change of the driving transistor T1 according to the SS, and VINI is the anode reset voltage of the LED.

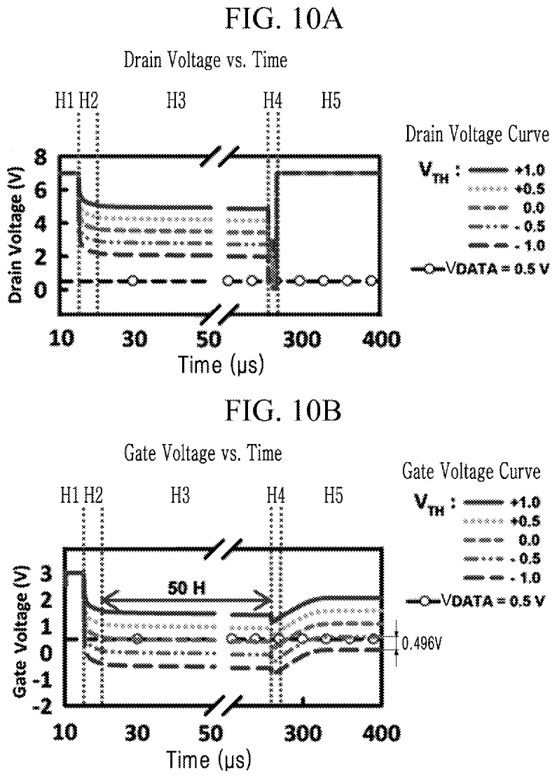

FIG. 10A is a waveform of the drain voltage and FIG. 10B is a waveform of the gate voltage according to the threshold voltage range of the driving transistor of the pixel circuit according to some embodiments.

In an experiment to obtain the waveform shown in FIG. 10A and FIG. 10B, the threshold voltage of the driving transistor is one of −1.0 V, −0.5 V, 0 V, 0.5 V, and 1.0 V, the period H3 is 50H (H is a horizontal period), and the data signal VDATA is 0.5 V.

As shown in FIG. 10B, it can be seen that during the light emitting period H5, the difference between the two gate voltages corresponding to two threshold voltages at any of −1.0 V, −0.5 V, 0 V, 0.5 V, and 1.0 V is equal to the difference between two threshold voltages at any of −1.0 V, −0.5 V, 0 V, 0.5 V, and 1.0 V. That is, it can be seen that the gate voltage is compensated according to the threshold voltage of the driving transistor. In FIG. 10B, it can be seen that the difference between a gate voltage VG1 for a threshold voltage of −0.5 V and a gate voltage VG2 for a threshold voltage of −1.0 V is 0.496 V, which is practically the same as the difference between the two threshold voltages (0.5 V).

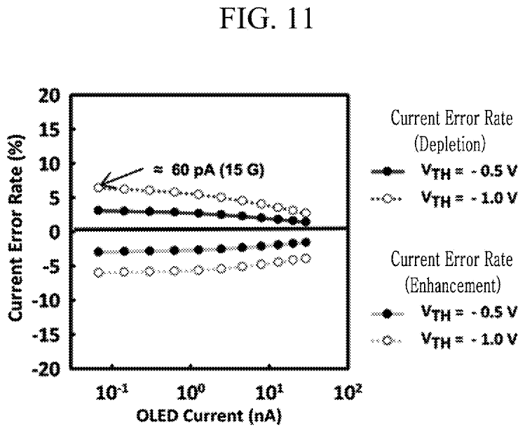

FIG. 11 is a graph showing the driving current error rate of the driving transistor operated according to FIG. 10.

In the experiment to obtain the current error rate shown in FIG. 11, the threshold voltage VTH in the depletion mode is −0.5 V and −1.0 V, and the threshold voltage VTH in the enhancement mode is 0.5 V and 1.0 V. The data signal VDAT is a voltage level corresponding to 15 grayscales (15G).

As shown in FIG. 11, it can be seen that the current error rate is very low because the threshold voltage is accurately reflected in the gate voltage. When ΔVTH=+0.5 V relative to VTH=0 V, the current error rate at VTH of 0.5 V and −0.5 V is within 4% of 60 [pA] in both the enhancement mode and the depletion mode. In the depletion mode, the current error rate between VTH=−0.5 V and VTH=−1.0 V is also within 4% of 60 [pA], and in the enhancement mode, the current error rate between VTH=0.5 V and VTH=1.0 V is also within 4% of 60 [pA].

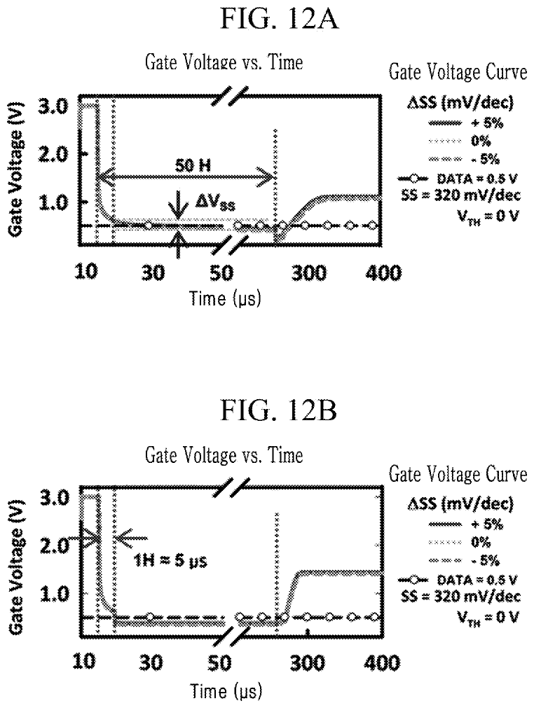

FIG. 12A and FIG. 12B are waveform diagrams showing the gate voltage transient by SS when the SS compensation period is varied.

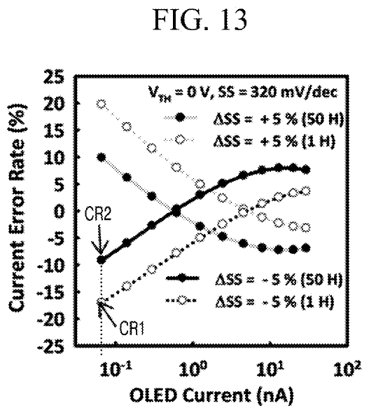

FIG. 13 is a graph showing the current error rate when the SS compensation period is varied.

FIG. 12A shows the transient waveform of the gate voltage by the SS when the compensation period is 50H and FIG. 12B shows the transient waveform of the gate voltage by the SS when the compensation period is 1H. As shown in FIG. 12A and FIG. 12B, it can be seen that the gate voltage decreases as the SS compensation period increases.

Then, as shown in FIG. 13, it can be seen that the uniformity in the low-grayscale region is improved. When the SS is 320 mV/dec, the variation of the SS (ΔSS) is +5%, the threshold voltage VTH is 0 V, and the SS compensation period is 50H, the current error CR2 due to the SS at low grayscale 15 is only about 10% of 60 pA

In FIG. 13, when the maximum value of the LED current is 30 nA, the LED current at low grayscale 15 is 60 pA. In contrast, under the same conditions, when the SS compensation period is 1H, the current error CR1 due to SS at low grayscale 15 is about 20% of 60 pA.

The human eye can distinguish display deviations better at low grayscale than at high grayscale. Therefore, display devices require greater display uniformity at low grayscale. In the timing diagram shown in FIG. 6, the SS compensation period may be sufficiently increased, thereby reducing the current error rate at low grayscale. As such, the pixel circuit according to some embodiments may improve uniformity at low grayscale by increasing the SS compensation period and reducing the SS deviation between the plurality of driving transistors.

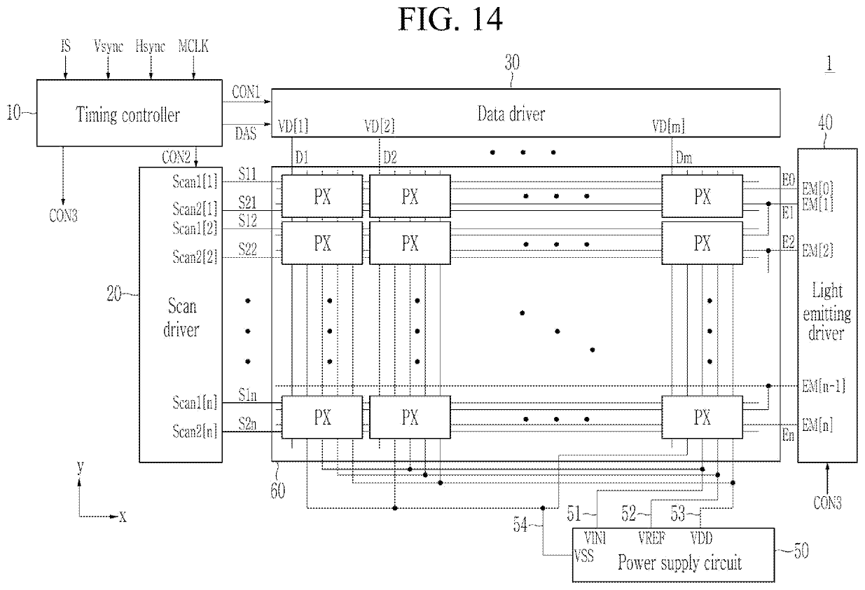

FIG. 14 illustrates a display device including the pixel circuit according to some embodiments.

As shown in FIG. 14, a display device 1 includes a timing controller 10, a scan driver 20, a data driver 30, a light emitting driver 40, a power supply circuit 50, and a display unit 60.

The timing controller 10 converts an image source IS provided externally into an image data signal DAS and transmits it to the data driver 30. The timing controller 10 receives a vertical synchronization signal Vsync, a horizontal synchronization signal Hsync, and a clock signal MCLK, and generates and transmits a plurality of control signals CON1, CON2, and CON3 to control the operation of each of the scan driver 20, the data driver 30, and the light emitting driver 40.

The display unit 60 may include a plurality of pixels PX, a plurality of first scan lines S11-S1n, a plurality of second scan lines S21-S2n, a plurality of data lines D1-Dm, a plurality of light emitting control lines EO-En, and four voltage supply lines 51-54. The plurality of pixels PX are arranged in a matrix form and may display at least one color among red, green, and blue. Each of the plurality of first scan lines S11-S1n extends in the x-axis direction, and the plurality of first scan lines S11-S1n are arranged in the y-axis direction. Each of the plurality of second scan lines S21-S2n extends in the x-axis direction, and the plurality of second scan lines S21-S2n are arranged in the y-axis direction. Each of the plurality of data lines D1-Dm extends in the y-axis direction, and the plurality of data lines D1-Dm are arranged in the x-axis direction. Each of the plurality of light emitting control lines EO-En extends in the x-axis direction, and the plurality of light emitting control lines EO-En are arranged in the y-axis direction. Each of the four voltage supply lines 51-54 includes a plurality of wirings branching in the x-axis direction, and each wiring may extend in the y-axis direction. In FIG. 14, the formation direction and arrangement of the plurality of first scan lines S11-S1n, the plurality of second scan lines S21-S2n, the plurality of data lines D1-Dm, the plurality of light emitting control lines EO-En, and the four voltage supply lines 51-54 are only examples for describing the present disclosure, and the present disclosure is not limited thereto.

Each of the plurality of pixels PX is connected to a corresponding one of the plurality of first scan lines S11-S1n and a corresponding one of the plurality of second scan lines S21-S2n, and each pixel PX may receive a corresponding first scan signal Scan1[i] (where i is one of the natural numbers from 1 to n) and a corresponding second scan signal Scan [i] through the corresponding first scan line and the second scan line. Each of the plurality of pixels PX is connected to a corresponding one of the plurality of data lines D1-Dm, and each pixel may receive a corresponding data signal through the corresponding data line. Each of the plurality of pixels PX is connected to two corresponding light emitting control lines among the plurality of light emitting control lines EO-En, and may receive two corresponding light emitting signals through the two corresponding light emitting control lines. Each of the plurality of pixels PX is connected to the four voltage supply lines 51-54, and each pixel PX may receive the initialization voltage VINI, the reference voltage VREF, and two power supply voltages VDD and VSS through the four voltage supply lines 51-54.

The configurations of each of the plurality of pixels PX and the connection relationships between the configurations are the same as the pixel circuit described with reference to FIG. 5, and the operating method of each of the plurality of pixels PX is the same as the operation of the pixel circuit described with reference to FIG. 6.

The scan driver 20 may generate a plurality of scan signals Scan1[1]-Scan1[n] and Scan2[1]-Scan2[n] according to the control signal CON2 and supply them to the plurality of first scan lines S11-S1n and the plurality of second scan lines S21-S2n.

The data driver 30 may convert an image data signal into a plurality of data signals VD[1]-VD[m] according to the control signal CON2, and supply each of the plurality of data signals VD[1]-VD[m] to the plurality of data lines D1-Dm.

The light emitting driver 40 may generate a plurality of light emitting control signals EM[0]-EM[n] according to the control signal CON3 and supply them to a plurality of light emitting control lines E0-En.

The power supply circuit 50 may generate and supply four voltages, the initialization voltage VINI, the reference voltage VREF, and two power voltages VSS and VDD, that are required to drive the plurality of pixels PX, to each of the four voltage lines 51, 52, 53, and 54.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

1. A pixel circuit, comprising:
a light emitting diode;
a first transistor including one end connected to the light emitting diode;
a first capacitor including one end connected to a gate of the first transistor;
a second capacitor including one end connected to another end of the first transistor;
a second transistor including one end connected to another end of the second capacitor and another end of the second transistor supplied with a reference voltage;
a third transistor including one end connected to another end of the first transistor and another end of the third transistor supplied with a power voltage; and
a fourth transistor including one end connected to another end of the second capacitor and another end of the fourth transistor connected to the gate of the first transistor,
wherein a first voltage, which is a data signal supplied to the one end of the first transistor plus a threshold voltage of the first transistor, is provided to the gate of the first transistor during an on period of the fourth transistor.

2. The pixel circuit of claim 1, wherein
the first voltage decreases by a gate voltage change by a subthreshold swing (SS) of the first transistor during the on period of the fourth transistor.

3. The pixel circuit of claim 1, further comprising
a fifth transistor including one end connected to the one end of the first transistor and another end of the fifth transistor supplied with the data signal; and
a sixth transistor including one end connected to another end of the first capacitor and another end of the sixth transistor supplied with an initialization voltage.

4. The pixel circuit of claim 3, wherein
a first scan signal is supplied to the gate of the fifth transistor, a second scan signal is supplied to the gate of the fourth transistor and the gate of the sixth transistor, and a first light emitting signal is supplied to the gate of the second transistor and the gate of the third transistor.

5. The pixel circuit of claim 4, wherein
in driving the pixel circuit,
a first period in which the second scan signal and the first light emitting signal are at the on level;
a second period in which the first scan signal and the second scan signal are at the on level;
a third period in which the second scan signal is at the on level; and
a fourth period in which the first light emitting signal is at the on level are divided.

6. The pixel circuit of claim 5, wherein
in the second period, the data signal is provided to the one end of the first transistor, and the first voltage is provided to the gate of the first transistor,
and in the third period, a gate voltage of the first transistor decreases by the amount of gate voltage change by the subthreshold swing (SS) of the first transistor.

7. The pixel circuit of claim 4, further comprising
a seventh transistor connected between the one end of the first transistor and the light emitting diode and including a gate to which a second light emitting signal at an on level is supplied a predetermined period earlier than the first light emitting signal.

8. The pixel circuit of claim 7, wherein
in driving the pixel circuit,
a first period in which the second scan signal and the first light emitting signal are at on level;
a second period in which the first scan signal and the second scan signal are at on level;
a third period in which the second scan signal is at on level; and
a fourth period in which the first light emitting signal and the second light emitting signal are at on level are divided.

9. The pixel circuit of claim 8, wherein
in the second period, the data signal is provided to the one end of the first transistor, and the first voltage is provided to the gate of the first transistor,
in the third period, a gate voltage of the first transistor decreases by the amount of gate voltage change by the subthreshold swing (SS) of the first transistor so that the gate of the first transistor becomes the second voltage,
and in the fourth period, a driving current generated by the first transistor according to the second voltage flows to the light emitting diode.

10. The pixel circuit of claim 7, wherein
the first to seventh transistors are implemented as oxide transistors.

11. A display device, comprising:
a plurality of first scan lines, a plurality of second scan lines, a plurality of data lines, a plurality of light emitting control lines, and a plurality of pixels,
wherein each of the plurality of pixels comprises
a light emitting diode;
a first transistor including one end connected to the light emitting diode;
a first capacitor including one end connected to a gate of the first transistor;
a second capacitor including one end connected to another end of the first transistor;
a second transistor including one end connected to another end of the second capacitor, another end of the second transistor supplied with a reference voltage, and a gate connected to a corresponding first light emitting control line among the plurality of light emitting control lines;
a third transistor including one end connected to the another end of the first transistor, another end of the third transistor supplied with a power voltage, and a gate connected to the first light emitting control line;
a fourth transistor including one end connected to another end of the second capacitor, another end of the fourth transistor connected to the gate of the first transistor, and a gate connected to a corresponding second scan line among the plurality of second scan lines; and
a fifth transistor including one end connected to the one end of the first transistor, another end of the fifth transistor connected to a corresponding first data line among the plurality of data lines, and a gate connected to a corresponding first scan line among the plurality of first scan lines.

12. The display device of claim 11, wherein
while a first scan signal at the on level is supplied through the corresponding first scan line and a second scan signal at the on level is supplied through the corresponding second scan line, a first voltage obtained by adding a threshold voltage of the first transistor to the data signal supplied to the one end of the first transistor is provided to the gate of the first transistor.

13. The display device of claim 12, wherein
while the first scan signal is at an off level and the second scan signal at the on level is supplied through the corresponding second scan line,
the first voltage decreases by a gate voltage change by a subthreshold swing (SS) of the first transistor during an on period of the fourth transistor.

14. The display device of claim 11, wherein
each of the plurality of pixels further comprises
a sixth transistor including one end connected to the one end of the first capacitor, another end of the sixth transistor supplied with an initialization voltage, and a gate connected to the corresponding second scan line; and
a seventh transistor connected between the one end of the first transistor and the light emitting diode, and including a gate connected to a second light emitting control line adjacent to the first light emitting control line among the plurality of light emitting control lines.

15. The display device of claim 14, wherein
while the first scan signal at the on level is supplied through the corresponding first scan line and the second scan signal at the on level is supplied through the corresponding second scan line, the first voltage obtained by adding the threshold voltage of the first transistor to the data signal supplied to the one end of the first transistor is provided to the gate of the first transistor,
while the first scan signal is at an off level and the second scan signal at the on level is supplied through the corresponding second scan line, a gate voltage of the first transistor decreases by the gate voltage change by the subthreshold swing (SS) of the first transistor to become a second voltage during the on period of the fourth transistor,
and while a light emitting signal at the on level is supplied to each of the first light emitting control line and the second light emitting control line, the first transistor provides a driving current according to the second voltage to the light emitting diode.

16. The display device of claim 15, wherein
while the first scan signal is at an off level, the second scan signal at the on level is supplied through the corresponding second scan line, and the light emitting signal at the on level is supplied to the first light emitting control line,
when the power voltage is applied to the another end of the first transistor and the initialization voltage is applied to an anode of the light emitting diode, the reference voltage is applied to the another end of the second capacitor.

17. The display device of claim 14, wherein
the first to seventh transistors are implemented as oxide transistors.
